(19) United States
(12) Patent Application Publication
(10) Pub. No.: US 2011/0061704 A1
(43) Pub. Date: Mar. 17, 2011

(54) THERMOELECTRIC CONVERSION MODULE AND METHOD FOR PRODUCING THE SAME

(75) Inventors: Takanori NAKAMURA, Nagaokakyo-shi (JP); Shuji MATSUMOTO, Nagaokakyo-shi (JP)

(73) Assignee: MURATA MANUFACTURING CO., LTD., Nagaokakyo-shi (JP)

(21) Appl. No.: 12/948,905

(22) Filed: Nov. 18, 2010

Related U.S. Application Data
(63) Continuation of application No. PCT/JP2009/059268, filed on May 20, 2009.

(30) Foreign Application Priority Data
May 23, 2008 (JP) 2008-135656

(51) Int. Cl. H01L 35/34; H01L 35/02; H01L 21/04

(52) U.S. Cl. 136/236.1; 438/54; 136/201; 257/E21.04

(57) ABSTRACT

A thermoelectric conversion module is formed by bonding a P-type thermoelectric conversion material and an N-type thermoelectric conversion material together with an insulating material including spherical ceramic grains having an index of grain size dispersion, 3CV, of about 20% or less interposed therebetween. The P-type thermoelectric conversion material and the N-type thermoelectric conversion material are electrically connected to each other in a region other than a region in which the P-type thermoelectric conversion material and the N-type thermoelectric conversion material are bonded together with the insulating material interposed therebetween. The spherical ceramic grains have an average grain size of about 0.05 mm to about 0.6 mm, and the insulating material is an insulating glass material.

### BACKGROUND OF THE INVENTION

1. Field of the Invention

The present invention relates to a thermoelectric conversion module and a method for producing the same. More specifically, the present invention relates to a thermoelectric conversion module which includes a P-type thermoelectric conversion material and an N-type thermoelectric conversion material bonded together with an insulating material interposed therebetween and which includes a high occupancy of the thermoelectric conversion materials per unit area and a method for producing such a thermoelectric conversion module.

2. Description of the Related Art

In recent years, carbon dioxide reduction has become a critical issue to prevent global warming. Therefore, attention has been directed to thermoelectric conversion elements that are capable of directly converting heat to electricity as one of effective method of waste heat recovery.

An example of a conventional thermoelectric conversion element is shown in FIG. 9. As shown in FIG. 9, the thermoelectric conversion element 50 includes a P-type thermoelectric conversion material 51, an N-type thermoelectric conversion material 52, low-temperature electrodes 56, and a high-temperature electrode 58.

In the thermoelectric conversion element 50, the two types of thermoelectric conversion materials 51 and 52 are provided to convert energy from heat to electricity. The thermoelectric conversion materials 51 and 52 are connected to the low-temperature electrodes 56 at their respective low-temperature junctions 53b. The low-temperature junctions 53b are defined by the end surfaces of the thermoelectric conversion materials 51 and 52 located on the low-temperature electrode side. Further, the thermoelectric conversion materials 51 and 52 are also connected to the high-temperature electrode 58 at their respective high-temperature junctions 53a, and the high-temperature electrode 58 connects the thermoelectric conversion materials 51 and 52 to each other. The high-temperature junctions 53a are defined by the end surfaces of the thermoelectric conversion materials 51 and 52 located on the high-temperature electrode side.

When a temperature difference is applied between the high-temperature junctions 53a and the low-temperature junctions 53b of the thermoelectric conversion element 50, an electromotive force is generated by the Seebeck effect, and therefore, electricity can be extracted from the thermoelectric conversion element 50.

Meanwhile, the electric-generating capacity of a thermoelectric conversion element depends on the thermoelectric conversion characteristics of the materials used or a temperature difference applied to the element, but is also significantly influenced by the occupancy of thermoelectric conversion materials (i.e., by the proportion of the area of a portion occupied by thermoelectric conversion materials in a plane perpendicular to a direction in which a temperature difference is applied to the thermoelectric conversion element). Therefore, the electric-generating capacity of a thermoelectric conversion element per unit area can be increased by increasing the occupancy of the thermoelectric conversion materials.

However, the conventional thermoelectric conversion element 50 includes an insulating gap layer provided between the two thermoelectric conversion materials 51 and 52. Therefore, there is a limit to the extent to which the occupancy of the thermoelectric conversion materials can be increased.

In order to overcome such a problem, a thermoelectric conversion module shown in FIGS. 10A and 10B (see, for example, JP-A-2000-286467) has been proposed. As shown in FIGS. 10A and 10B, the thermoelectric conversion module is formed by bonding the P-type thermoelectric conversion material 51 and the N-type thermoelectric conversion material 52 together with an insulating layer 61 interposed therebetween, and electrodes 62 are provided on the upper and lower surfaces of the P-type and N-type thermoelectric conversion materials 51 and 52 to electrically connect the P-type and N-type thermoelectric conversion materials 51 and 52 to each other.

More specifically, as shown in FIG. 10B, the side surface (bonding surface) of the P-type thermoelectric conversion material 51 and the side surface (bonding surface) of the N-type thermoelectric conversion material 52 are bonded together with the insulating layer 61 interposed therebetween, and the electrode 62 is provided on the upper surfaces of the P-type and N-type thermoelectric conversion materials 51 and 52 to electrically connect the P-type and N-type thermoelectric conversion materials 51 and 52 to each other. The electrode 62 comprises carbon electrodes 71, a nickel-based wax 72, and a molybdenum electrode 73. The nickel-based wax 72 and the molybdenum electrode 73 are stacked in this order on the carbon electrodes 71 provided on the upper surfaces of the P-type and N-type thermoelectric conversion materials 51 and 52, respectively.

The insulating layer 61 is made of an electrically insulating material obtained by dispersing ceramic grains in a glass matrix.

Since the thermoelectric conversion module described above is formed by bonding the P-type thermoelectric conversion material 51 and the N-type thermoelectric conversion material 52 together with the insulating layer 61 interposed therebetween, there is no need to provide a space between the P-type thermoelectric conversion material 51 and the N-type thermoelectric conversion material 52. This makes it possible to achieve a relatively high occupancy of the thermoelectric conversion materials, thereby improving electric-generating capacity per unit area.

However, such a conventional thermoelectric conversion module formed by bonding the P-type and N-type thermoelectric conversion materials 51 and 52 together using an electrically insulating material obtained by dispersing ceramic grains in a glass matrix often has poor reliability. This is because if the grain size distribution of ceramic grains 61a is wide, as schematically shown in FIG. 11, there is a problem that the bonding surfaces of the P-type and N-type thermoelectric conversion materials 51 and 52 are not arranged parallel to each other and therefore come into contact with each other at their ends (in a position represented as a point P in FIG. 11), thereby causing a short circuit.

Further, if the bonding surfaces of the P-type and N-type thermoelectric conversion materials 51 and 52 bonded together with the insulating layer 61 interposed therebetween are not arranged parallel to each other, there is also a problem that the P-type and N-type thermoelectric conversion materials 51 and 52 cannot be properly aligned and therefore the occupancy of the thermoelectric conversion materials cannot be sufficiently improved.

### SUMMARY OF THE INVENTION

To overcome the problems described above, preferred embodiments of the present invention provide a highly-reliable thermoelectric conversion module including a P-type thermoelectric conversion material and an N-type thermoelectric conversion material that are bonded together with an insulating material interposed therebetween, and capable of ensuring insulation between the bonding surfaces of the P-type thermoelectric conversion material and the N-type thermoelectric conversion material, and achieve a high occupancy of the thermoelectric conversion materials, and provide a method for producing such a thermoelectric conversion module.

A thermoelectric conversion module according to a preferred embodiment of the present invention includes a P-type thermoelectric conversion material, an N-type thermoelectric conversion material, and an insulating material including spherical ceramic grains preferably having an index of particle size dispersion, 3CV, of about 20% or less, for example. The P-type thermoelectric conversion material and the N-type thermoelectric material are bonded together with the insulating material interposed therebetween. In a region other than a region in which the P-type thermoelectric conversion material and the N-type thermoelectric conversion material are bonded together with the insulating material interposed therebetween, the P-type thermoelectric conversion material and the N-type thermoelectric conversion material are electrically connected to each other.

Preferably, the spherical ceramic grains have an average grain size of about 0.05 mm to about 0.6 mm, for example.

Preferably, the insulating material is an insulating glass material, for example.

A method for producing a thermoelectric conversion module according to a preferred embodiment of the present invention is a method for producing a thermoelectric conversion module including a P-type thermoelectric conversion material and an N-type thermoelectric conversion material which are bonded together with an insulating material interposed therebetween and which are electrically connected to each other in a region other than a region in which the P-type thermoelectric conversion material and the N-type thermoelectric conversion material are bonded together with the insulating material interposed therebetween, the method including the steps of preparing a P-type thermoelectric conversion material and an N-type thermoelectric conversion material, applying an insulating material paste onto at least one of bonding surfaces of the P-type thermoelectric conversion material and the N-type thermoelectric conversion material to be bonded together with the insulating material interposed therebetween, when the insulating material paste is applied onto both the bonding surfaces to be bonded together, attaching spherical ceramic grains preferably having a 3CV value, which size dispersion, of about 20% or less, 3CV, for example, to at least one of the bonding surfaces so that the spherical ceramic grains are held by the insulating material paste, or when the insulating material paste is applied onto only one of the bonding surfaces to be bonded together, attaching spherical ceramic grains preferably having an index of grain size dispersion, 3CV, of about 20% or less, for example, to the one bonding surface onto which the insulating material paste is applied so that the spherical ceramic grains are held by the insulating material paste, and sticking the P-type thermoelectric conversion material and the N-type thermoelectric conversion material together with the insulating material paste including the spherical ceramic grains interposed therebetween and then bonding the P-type thermoelectric conversion material and the N-type thermoelectric conversion material together by thermal treatment.

Preferably, the spherical ceramic grains have an average grain size of about 0.05 mm to about 0.6 mm, for example.

Preferably, the insulating material is an insulating glass material, for example.

The thermoelectric conversion module according to a preferred embodiment of the present invention is preferably formed by bonding a P-type thermoelectric conversion material and an N-type thermoelectric conversion material together with an insulating material including spherical ceramic grains preferably having an index of grain size dispersion, 3CV, of about 20% or less, for example, interposed therebetween. Therefore, the P-type thermoelectric conversion material and the N-type thermoelectric conversion material can be arranged with no space therebetween. This makes it possible to provide a thermoelectric conversion module capable of achieving a high occupancy of the thermoelectric conversion materials and a high electric-generating capacity per unit area.

Further, the spherical ceramic grains of the insulating material preferably have a 3CV value of about 20% or less, for example (i.e., have a small grain size distribution). Therefore, as schematically shown in FIG. 2, the bonding surfaces of a P-type thermoelectric conversion material 1 and an N-type thermoelectric conversion material 2 are arranged substantially parallel to each other so as to be opposed to each other and spaced at substantially equal distances from each other at all points, and thus, a plurality of the P-type thermoelectric conversion material 1 and a plurality of the N-type thermoelectric conversion material 2 can be reliably arranged in proper alignment. This makes it possible to provide a highly-reliable thermoelectric conversion module having a high occupancy of the thermoelectric conversion materials.

When the spherical ceramic grains have an average grain size of about 0.05 mm to about 0.6 mm, for example, the P-type thermoelectric conversion material and the N-type thermoelectric conversion material can be more reliably bonded together so that the bonding surfaces of the P-type thermoelectric conversion material and the N-type thermoelectric conversion material are arranged substantially parallel to each other so as to be opposed to each other and spaced at substantially equal distances at all points. This makes it possible to more reliably provide a highly-reliable thermoelectric conversion module having a high occupancy of the thermoelectric conversion materials.

Therefore, the spherical ceramic grains preferably have an average grain size of about 0.05 mm to about 0.6 mm, for example. If the average grain size of the spherical ceramic grains is less than 0.05 mm, it is difficult to maintain an adequate distance between the bonding surfaces. On the other hand, if the average grain size of the spherical ceramic grains exceeds about 0.6 mm, the distance between the opposing bonding surfaces of the thermoelectric conversion materials becomes too large, and therefore, the occupancy of thermoelectric conversion materials cannot be sufficiently increased.

Further, when the insulating material is an insulating glass material, the P-type thermoelectric conversion material and the N-type thermoelectric conversion material can be reliably bonded together while insulation between the P-type thermoelectric conversion material and the N-type thermoelectric conversion material is ensured. This makes it possible to provide a highly-reliable thermoelectric conversion module.

In the method for producing a thermoelectric conversion module according to a preferred embodiment of the present invention, an insulating material paste is applied onto at least one of the bonding surfaces of a P-type thermoelectric conversion material and an N-type thermoelectric conversion material to be bonded together with an insulating material interposed therebetween. When the insulating material paste is applied onto both of the bonding surfaces to be bonded together, spherical ceramic grains preferably having a 3CV value of about 20% or less, for example, are attached to at least one of the bonding surfaces so as to be held by the insulating material paste. When the insulating material paste is applied onto only one of the bonding surfaces to be bonded together, spherical ceramic grains preferably having a 3CV value of about 20% or less, for example, are attached to the one bonding surface, onto which the insulating material paste has been applied, so as to be held by the insulating material paste. Then, the P-type thermoelectric conversion material and the N-type thermoelectric conversion material are stuck together with the insulating material paste including the spherical ceramic grains, and are then bonded together by heat treatment. Therefore, the P-type thermoelectric conversion material and the N-type thermoelectric conversion material can be arranged with no space therebetween while the bonding surfaces of the P-type thermoelectric conversion material and the N-type thermoelectric conversion material are reliably prevented from coming into direct contact with each other. This makes it possible to efficiently produce a highly-reliable thermoelectric conversion module having a high occupancy of the thermoelectric conversion materials.

When the spherical ceramic grains have an average grain size of about 0.05 mm to about 0.6 mm, for example, the P-type thermoelectric conversion material and the N-type thermoelectric conversion material can be bonded together so that the bonding surfaces of the P-type thermoelectric conversion material and the N-type thermoelectric conversion material are arranged substantially parallel to each other so as to be opposed to each other and spaced at substantially equal distances at all points. This makes it possible to more reliably produce a highly-reliable thermoelectric conversion module having a high occupancy of the thermoelectric conversion materials.

When the insulating material is an insulating glass material, the P-type thermoelectric conversion material and the N-type thermoelectric conversion material can be reliably bonded together while insulation between the P-type thermoelectric conversion material and the N-type thermoelectric conversion material is ensured. This makes it possible to efficiently produce a highly-reliable thermoelectric conversion module having a high occupancy of the thermoelectric conversion materials.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a plan view of a thermoelectric conversion module according to a preferred embodiment of the present invention.

FIG. 2 is a front sectional view of a principal portion of the thermoelectric conversion module shown in FIG. 1.

FIG. 3 is a diagram showing one step of a method for producing the thermoelectric conversion module according to a preferred embodiment of the present invention.

FIG. 4 is a diagram showing another step of the method for producing the thermoelectric conversion module according to a preferred embodiment of the present invention.

FIG. 5 is a diagram showing the step of arranging spherical ceramic grains (spherical zirconium oxide beads) on a glass paste applied onto side surfaces of thermoelectric elements in the method for producing the thermoelectric conversion module according to a preferred embodiment of the present invention.

FIG. 6 is a diagram showing the step of bonding the thermoelectric elements together in the method for producing the thermoelectric conversion module according to a preferred embodiment of the present invention.

FIG. 7 is a diagram showing the step of connecting the thermoelectric elements to each other in series by electrodes in the method for producing the thermoelectric conversion module according to a preferred embodiment of the present invention.

FIG. 8 is a schematic plan view of a thermoelectric conversion module according to a comparative example.

FIG. 9 is a diagram of a conventional thermoelectric conversion module.

FIG. 10A is a plan view of another conventional thermoelectric conversion module and FIG. 10B is an expanded view of a principal portion of the conventional thermoelectric conversion module shown in FIG. 10A.

FIG. 11 is a diagram to explain a problem of the conventional thermoelectric conversion module shown in FIG. 9.

### DETAILED DESCRIPTION OF THE PREFERRED EMBODIMENTS

Preferred embodiments of the present invention will be described below in more detail with reference to the drawings.

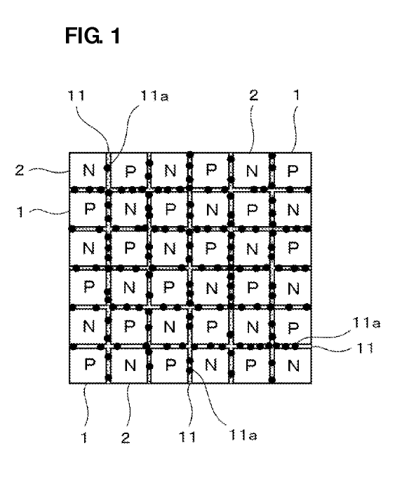

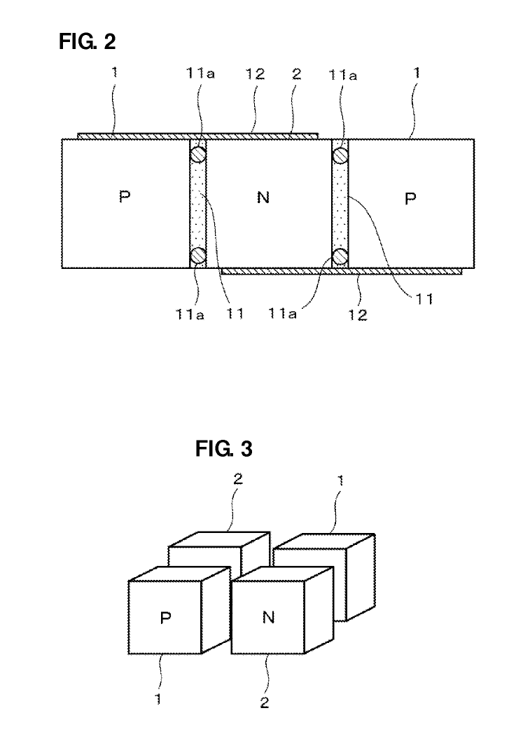

FIG. 1 is a plan view of a thermoelectric conversion module according to a preferred embodiment of the present invention, and FIG. 2 is an expanded front sectional view of a principal portion of the thermoelectric conversion module shown in FIG. 1.

As shown in FIGS. 1 and 2, the thermoelectric conversion module according to a preferred embodiment of the present invention is preferably formed by bonding thermoelectric elements (P-type thermoelectric conversion material 1 and N-type thermoelectric conversion material 2) together with an insulating material (in this preferred embodiment, an insulating glass material) 11 including spherical ceramic grains 11a preferably having an index of grain size dispersion, of about 20% or less, 3CV, for example, and an average grain size of 0.05 to 0.6 mm, for example, interposed therebetween. Further, electrodes 12 (not shown in FIG. 1 but see FIG. 2) are provided in a region other than a region in which the thermoelectric elements are bonded together with the insulating material 11 (in this example, on the upper and lower surfaces of the thermoelectric conversion module) so that the P-type thermoelectric conversion material 1 and the N-type thermoelectric conversion material 2 are electrically connected to each other in series. It is to be noted that the thermoelectric conversion module according to this preferred embodiment preferably includes a total of 36 thermoelectric elements (6 rows and 6 columns), for example.

However, the arrangement of the P-type thermoelectric conversion material 1 and the arrangement of the N-type thermoelectric conversion material 2, the number of the P-type thermoelectric conversion materials 1 used, and the number of the N-type thermoelectric conversion materials 2 used of the thermoelectric conversion module are not limited to those of the present preferred embodiment.

Further, the arrangement or layout of the electrodes to connect each P-type thermoelectric conversion material 1 and each N-type thermoelectric conversion material 2 to each other in series is not particularly limited, and can be determined based on the size and shape of each thermoelectric element used and the number of thermoelectric elements used.

As described above, the thermoelectric conversion module according to the present preferred embodiment is formed preferably by bonding the P-type thermoelectric conversion material 1 and the N-type thermoelectric conversion material 2 together with the insulating material 11 including the spherical ceramic grains 11a preferably having a 3CV value of grain size of about 20% or less, for example, (i.e., having a narrow grain size distribution). Therefore, as shown in FIGS. 1 and 2, the bonding surfaces of the P-type thermoelectric conversion material 1 and the N-type thermoelectric conversion material 2 are arranged substantially parallel to each other so as to be opposed to each other and spaced at substantially equal distances at all points. This makes it possible to arrange the P-type thermoelectric conversion material 1 and the N-type thermoelectric conversion material 2 with no space therebetween while reliably preventing the bonding surfaces of the P-type thermoelectric conversion material 1 and the N-type thermoelectric conversion material 2 from coming into direct contact with each other. As a result, it is possible to obtain a highly-reliable thermoelectric conversion module having a high occupancy of the thermoelectric conversion materials.

As described above, the bonding surfaces of the P-type thermoelectric conversion material 1 and the N-type thermoelectric conversion material 2 are arranged substantially parallel to each other so as to be opposed to each other and spaced at substantially equal distances at all points. Therefore, a plurality of the P-type thermoelectric conversion material 1 and a plurality of the N-type thermoelectric conversion material 2 can be properly aligned when each P-type thermoelectric conversion material 1 and each N-type thermoelectric conversion material 2 are bonded together with the insulating material 11 interposed therebetween. This makes it possible to obtain a highly-reliable thermoelectric conversion module having an increased occupancy of the thermoelectric conversion materials.

A method for producing the thermoelectric conversion module according to this preferred embodiment will be described below.

La₂O₃, Nd₂O₃, CeO₂, SrCO₃, and CuO were prepared as raw material powders and weighed according to the predetermined compositions of (La_{1.98}Sr_{0.02})CuO₄ and (Nd_{1.98}Ce_{0.02})CuO₄ to obtain a P-type thermoelectric conversion material and an N-type thermoelectric conversion material, respectively.

In this case, oxides of La, Nd, Ce, and Cu and a carbonate of Sr were preferably used as raw material powders, for example. However, starting materials are not limited to oxides and carbonates such as those mentioned above, and may be other inorganic materials, such as hydroxides, or organic metal compounds, such as acetylacetonato complexes.

The raw material powders weighed according to each of the compositions were milled and mixed in a wet ball mill using pure water as a solvent to obtain a slurry. Then, the slurry including the raw material powders was evaporated to obtain a mixed powder.

Then, the mixed powder was heated at about 900° C. for about 8 hours in an air atmosphere to prepare a target oxide powder for thermoelectric conversion material. It is to be noted that at this time, an unreacted portion may remain.

An organic binder was mixed with each of the oxide powders for thermoelectric conversion material obtained by a heat treatment in an amount of about 5 wt % with respect to the amount of each of the composition powders, and the resulting mixture was milled and mixed in a wet ball mill using pure water as a solvent.

Each of the composition powders including the organic binder was sufficiently dried, and was then molded using a uniaxial pressing machine at a pressure of about 10 MPa to prepare a molded body.

This molded body made of each of the oxide powders for thermoelectric conversion material was fired at about 1000° C. to about 1100° C. for about 2 hours in an air atmosphere to prepare a sintered product.

It is to be noted that the firing temperature at this time varies depending on the composition of each of the oxide powders for thermoelectric conversion material. Usually, conditions are set so that a relative density is preferably about 80% or greater, for example, and more preferably about 90% or greater, for example.

As shown in FIG. 3, the sintered products were cut into pieces each preferably having a size of about 5 mm×about 5 mm×about 5 mm by a dicing saw to obtain thermoelectric elements (P-type thermoelectric conversion material 1 and N-type thermoelectric conversion material 2).

Then, as shown in Table 1, three types of spherical zirconium oxide beads No. 1, No. 2, and No. 3 different in average grain size were prepared as spherical ceramic grains. It is to be noted that these spherical zirconium oxide beads are commercially available.

Then, the diameters of 100 beads of each of the three types of spherical zirconium oxide beads Nos. 1 to 3 were measured to determine an average grain size X, a standard deviation σ, and a 3CV value (=3σ/X). The results are shown in Table 1.

TABLE 1

| | | Standard | |
|---|---|---|---|
| | Average Grain | Deviation of | 3CV of Grain |
| | Size | Grain Size | Size |
| Type of Beads | (mm) | (mm) | (%) |
| Spherical | 0.54 | 0.034 | 19 |
| Zirconium | | | |
| Oxide Beads 1 | | | |
| Spherical | 0.12 | 0.0068 | 17 |
| Zirconium | | | |
| Oxide Beads 2 | | | |
| Spherical | 0.05 | 0.0032 | 19 |
| Zirconium | | | |
| Oxide Beads 3 | | | |

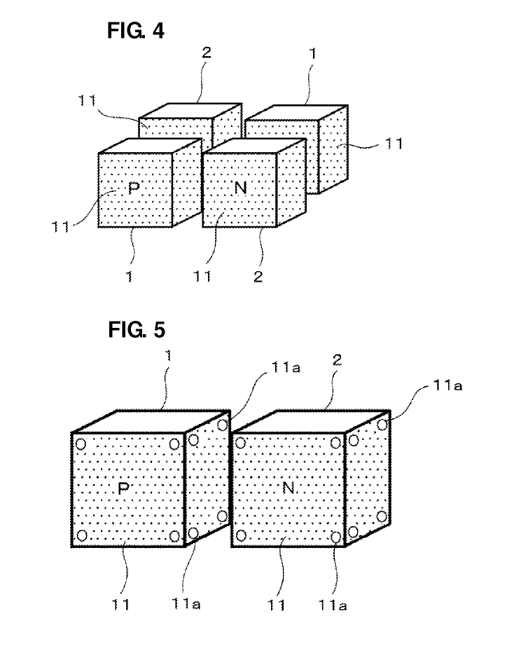

Then, as shown in FIG. 4, a glass paste (baked insulating material) 11 was applied onto four side surfaces other than conductive surfaces of each of the thermoelectric elements.

Then, as shown in FIG. 5, at least one spherical zirconium oxide bead 11a was arranged in the four corners of each of the surfaces, onto which the glass paste 11 had been applied, before the glass paste 11 was dried.

Then, one surface of a thermoelectric element 1, on which the spherical zirconium oxide beads 11a had been arranged, was temporarily bonded to a bonding surface of another thermoelectric element 2, onto which the glass paste 11 had been applied. In this manner, a pair of the P-type thermoelectric conversion material 1 and the N-type thermoelectric conversion material 12 was prepared. The pairs of the thermoelectric elements were arranged as shown in FIG. 1, and all of the thermoelectric elements were temporarily bonded together and dried in an oven at about 150° C.

It is to be noted that the glass paste is not particularly limited as long as it can hold the spherical zirconium oxide beads (spherical ceramic grains), and it is preferable that the composition and concentration of the glass paste are appropriately selected depending on the type, size, and shape of spherical ceramic grains used.

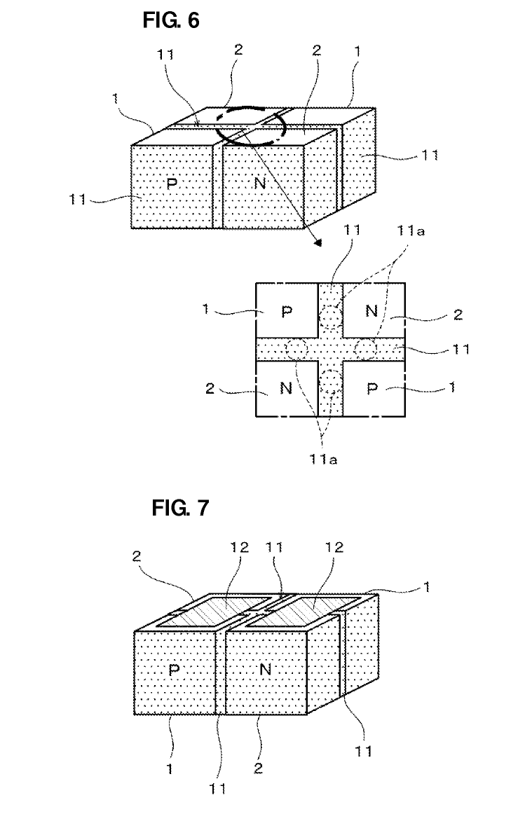

Then, a block obtained by bonding the thermoelectric elements (P-type thermoelectric conversion material 1 and N-type thermoelectric conversion material 2) together as described above was introduced into a tunnel furnace heated at about 900° C. to melt a glass component of the insulating material in a nitrogen atmosphere. As a result, as shown in FIG. 6, the thermoelectric elements were bonded together.

Then, conductive surfaces, that is, upper and lower surfaces of the block obtained by bonding the thermoelectric elements together, were polished.

As shown in FIG. 7, a Cu paste (electrodes 12 before firing) was applied onto the polished surfaces by screen printing to connect the thermoelectric elements (P-type thermoelectric conversion material 1 and N-type thermoelectric conversion material 2) to each other in series, and was then baked at about 860° C. in a nitrogen atmosphere. As a result, thermoelectric conversion modules (samples according to Examples 1 to 3 and Comparative Examples 1 to 3 shown in Table 2) in which, as shown in FIG. 1, the P-type thermoelectric conversion material 1 and the N-type thermoelectric conversion material 2 were connected to each other in series by the electrodes 12 (see FIG. 2) were prepared (in FIG. 1, the electrodes connecting the P-type thermoelectric conversion material 1 and the N-type thermoelectric conversion material 2 to each other are not shown).

As shown in Table 2, the sample according to Example 1 used the spherical zirconium oxide beads No. 1 shown in Table 1 having an average grain size of about 0.54 mm, a standard derivative of grain size of about 0.034 mm, and a 3CV value of about 19%.

The sample according to Example 2 used the spherical zirconium oxide beads No. 2 shown in Table 1 having an average grain size of about 0.12 mm, a standard deviation of grain size of about 0.0068 mm, and a 3CV value of about 17%.

The sample according to Example 3 used the spherical zirconium oxide beads No. 3 shown in Table 1 having an average grain size of about 0.05 mm, a standard deviation of grain size of about 0.0032 mm, and a 3CV value of about 19%.

The sample according to Comparative Example 1 was prepared by bonding the thermoelectric elements together with an insulating material made of only the glass paste without arranging spherical zirconium oxide beads (ceramic grains) on the glass paste.

Each of the samples according to Comparative Examples 2 and 3 used a mixture obtained by blending the spherical zirconium oxide beads Nos. 1 to 3 in a ratio shown in Table 2 to examine the influence of grain size dispersion of spherical ceramic grains.

The characteristics of the samples were evaluated in the following manner.

The bondability between the thermoelectric elements and glass of each of the samples was evaluated by visual observation.

As a result, all of the samples according to Examples 1 to 3 and Comparative Examples 1 to 3 were free from detachment, cracking, or chipping due to tight bonding between the thermoelectric elements.

The insulation between the thermoelectric elements was evaluated by measuring the resistance between the thermoelectric elements.

The relationship between the properties (grain size and content rate) of the spherical zirconium oxide beads included in the insulating material used in each of the samples and the resistance between the thermoelectric elements defining the thermoelectric conversion module is shown in Table 2.

TABLE 2

| | Blending Ratio | | | |
|---|---|---|---|---|
| | of Spherical Zirconium | | | |
| | Oxide Beads (wt %) | | | |
| | | Spherical | | Resistance |
| | Spherical | Zirconium | Spherical | between |
| | Zirconium | Oxide | Zirconium | Elements |
| Samples | Oxide Beads 1 | Beads 2 | Oxide Beads 3 | (Ω) |
| Sample of | 100 | 0 | 0 | 10⁵-10⁶ |
| Example 1 | | | | |
| Sample of | 0 | 100 | 0 | 10⁴-10⁵ |
| Example 2 | | | | |
| Sample of | 0 | 0 | 100 | 10⁷-10⁸ |
| Example 3 | | | | |
| Sample of | 0 | 0 | 0 | 0.1-1.0 |
| Comparative | | | | |
| Example 1 | | | | |
| Sample of | 90 | 5 | 5 | 0.1-1.0 |
| Comparative | | | | |
| Example 2 | | | | |
| Sample of | 50 | 45 | 5 | 0.1-1.0 |
| Comparative | | | | |
| Example 3 | | | | |

As shown in Table 2, in the case of the sample according to Comparative Example 1 prepared without arranging spherical zirconium oxide beads on glass, the resistance between the thermoelectric elements was about 0.1Ω to about 1.0Ω, that is, the insulation between the thermoelectric elements was not ensured.

Also in the cases of Comparative Examples 2 and 3 using a mixture of the spherical zirconium oxide beads different in grain size, the resistance between the thermoelectric elements was about 0.1Ω to about 1.0Ω, that is, insulation between the thermoelectric elements was not ensured. This is because bonding surfaces of the thermoelectric elements to be connected to each other are not arranged parallel or substantially parallel to each other and, therefore, come into contact with each other at their ends.

Further, in the cases of Comparative Examples 2 and 3 using a mixture of the spherical zirconium oxide beads having different grain sizes, the bonding surfaces of the thermoelectric elements were not arranged parallel or substantially parallel to each other, and, therefore, the thermoelectric elements could not be properly aligned. This is disadvantageous in that the occupancy of the thermoelectric elements is significantly reduced.

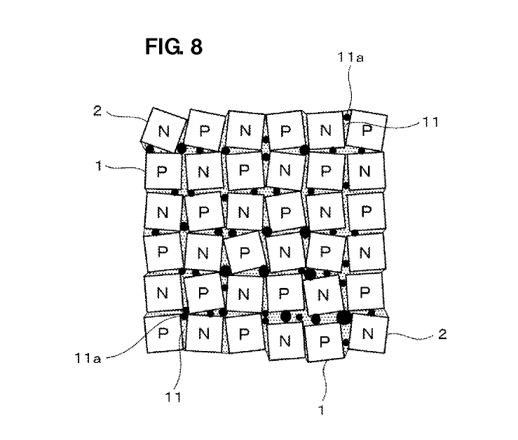

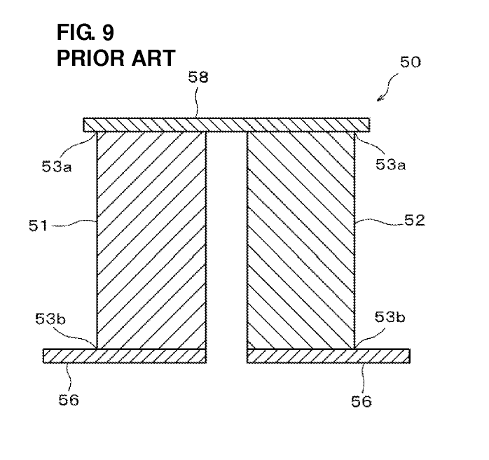

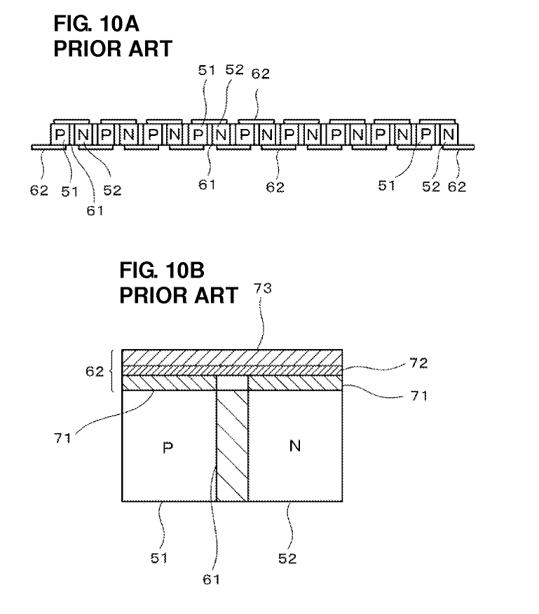

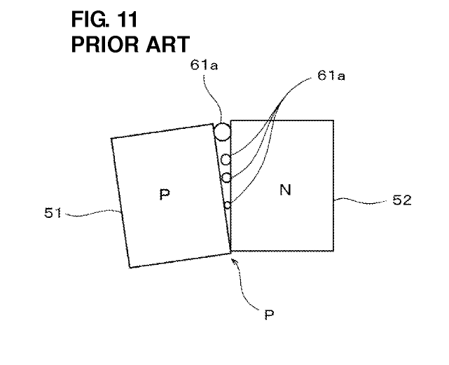

FIG. 8 is a plan view schematically showing the thermoelectric conversion module according to Comparative Example 3. As shown in FIG. 8, when a mixture of the spherical zirconium oxide beads having different grain sizes was used, bonding surfaces of the thermoelectric elements were not arranged parallel or substantially parallel to each other, and, therefore, the thermoelectric elements could not be properly aligned. Therefore, the thermoelectric elements came into contact with each other and the insulation between the thermoelectric elements was not ensured. In addition, the occupancy of the thermoelectric elements was significantly reduced.

On the other hand, in the cases of the samples according to Examples 1 to 3 (see FIGS. 1 and 2) using the insulating material including any one of the three types of spherical zirconium oxide beads 1, 2, and 3 having a 3CV value (which is an index of grain size dispersion) of about 20% or less to ensure insulation between the thermoelectric elements, the resistance between the thermoelectric elements was about 10⁴Ω to about 10⁷Ω, that is, outstanding insulation between the thermoelectric elements was ensured.

Further, in the cases of the samples according to Examples 1 to 3, the bonding surfaces of the thermoelectric elements were arranged parallel or substantially parallel to each other, and, therefore, the thermoelectric elements could be properly aligned so that a high occupancy of the thermoelectric elements was achieved.

It is to be noted that the present invention has been described with reference to examples of preferred embodiments including spherical zirconium oxide beads as spherical ceramic grains. However, the spherical ceramic grains to be used in preferred embodiments of the present invention are not particularly limited, and may be any spherical ceramic grains as long as they are made of a ceramic material, such as alumina, titania, or other suitable ceramic material, for example.

Further, in the preferred embodiments described above, insulating glass is preferably used as an insulating material. However, a resin-based material, for example, may be used as an insulating material instead of insulating glass.

Various applications and modifications may be made within the scope of the present invention regarding, for example, the compositions and raw materials of the P-type thermoelectric conversion material and the N-type thermoelectric conversion material, the specific structure of the thermoelectric conversion module, and specific production conditions, e.g., sizes, firing conditions, and the number of thermoelectric elements included in the thermoelectric conversion module.

As described above, according to preferred embodiments of the present invention, it is possible to obtain a highly-reliable thermoelectric conversion module which is formed by bonding a P-type thermoelectric conversion material and an N-type thermoelectric conversion material together with an insulating material interposed therebetween, and is capable of reliably ensuring insulation between the bonding surfaces of the P-type thermoelectric conversion material and the N-type thermoelectric conversion material, and has a high occupancy of thermoelectric elements.

Therefore, preferred embodiments of the present invention can be widely applied to the field of thermoelectric conversion modules which must have a high occupancy of thermoelectric conversion elements and high reliability.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A thermoelectric conversion module comprising:
a P-type thermoelectric conversion material;
an N-type thermoelectric conversion material; and
an insulating material including spherical ceramic grains having an index of particle size dispersion, 3CV, of about 20% or less; wherein
the P-type thermoelectric conversion material and the N-type thermoelectric material are bonded together with the insulating material interposed therebetween: and
in a region other than a region in which the P-type thermoelectric conversion material and the N-type thermoelectric conversion material are bonded together with the insulating material interposed therebetween, the P-type thermoelectric conversion material and the N-type thermoelectric conversion material are electrically connected to each other.

2. The thermoelectric conversion module according to claim 1, wherein the spherical ceramic grains have an average grain size of about 0.05 mm to about 0.6 mm.

3. The thermoelectric conversion module according to claim 1, wherein the insulating material is an insulating glass material.

4. A method for producing a thermoelectric conversion module including a P-type thermoelectric conversion material and an N-type thermoelectric conversion material which are bonded together with an insulating material interposed therebetween and which are electrically connected to each other in a region other than a region where they are bonded together with the insulating material interposed therebetween, the method comprising the steps of:
preparing a P-type thermoelectric conversion material and an N-type thermoelectric conversion material;
applying an insulating material paste onto at least one of bonding surfaces of the P-type thermoelectric conversion material and the N-type thermoelectric conversion material to be bonded together with the insulating material interposed therebetween;
when the insulating material paste is applied onto both of the bonding surfaces to be bonded together, attaching spherical ceramic grains having an index of grain size dispersion, 3CV, of about 20% or less to at least one of the bonding surfaces so that the spherical ceramic grains are held by the insulating material paste, or when the insulating material paste is applied onto only one of the bonding surfaces to be bonded together, attaching spherical ceramic grains having an index of grain size dispersion, 3VC, of about 20% or less to the one bonding surface onto which the insulating material paste is applied so that the spherical ceramic grains are held by the insulating material paste; and
sticking the P-type thermoelectric conversion material and the N-type thermoelectric conversion material together with the insulating material paste including the spherical ceramic grains interposed therebetween and then bonding the P-type thermoelectric conversion material and the N-type thermoelectric conversion material together by thermal treatment.

5. The method for producing a thermoelectric conversion module according to claim 4, wherein the spherical ceramic grains have an average grain size of about 0.05 mm to about 0.6 mm.

6. The method for producing a thermoelectric conversion module according to claim 4, wherein the insulating material is an insulating glass material.
